(19) United States
(12) Patent Application Publication
(10) Pub. No.: US 2025/0098185 A1
(43) Pub. Date: Mar. 20, 2025

(54) Electronic Device with Three-Dimensional On-Chip Inductors

(71) Applicant: Apple Inc., Cupertino, CA (US)

(72) Inventors: Ming-Da Tsai, San Jose, CA (US); Haowei Jiang, San Diego, CA (US)

(21) Appl. No.: 18/470,581

(22) Filed: Sep. 20, 2023

(51) Int. Cl. H01L 23/66; H01F 27/28; H01F 27/29

(52) U.S. Cl. CPC H10D 1/20; H01L 23/66; H01F 27/2804; H01F 27/29; H01L 2223/6677

(57) ABSTRACT

An electronic device may include wireless circuitry. The wireless circuitry may include inductors. The inductors may include an on-chip three-dimensional (3D) inductor. The 3D inductor may include a stack of windings in different metallization layers of the substrate. The 3D inductor may include at least one additional winding formed from at least one of the same metallization layers as the stack of windings. The at least one additional winding may laterally surround at least one of the windings from the stack of windings. The stack of windings may be vertically aligned or staggered. The at least one additional winding may be arranged in a vertically aligned stack or a staggered stack. Two or more stacks of windings may be separated by a winding between the stacks. The inductor may occupy a minimal amount of area while minimizing fringing capacitance, thereby optimizing quality factor and self-resonance frequency.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas that convey radio-frequency signals.

The wireless communications circuitry may include inductors that are used in conveying the radio-frequency signals. It can be challenging to provide the inductors with sufficient levels of performance. In addition, if care is not taken, the inductors can consume an excessive amount of area in the device.

### SUMMARY

An electronic device may include wireless circuitry. The wireless circuitry may include inductors. The inductors may include on-chip inductors on a semiconductor substrate. The on-chip inductors may include a three-dimensional (3D) inductor.

The 3D inductor may include a stack of windings in different metallization layers of the substrate. The 3D inductor may include at least one additional winding formed from at least one of the same metallization layers as the stack of windings. The at least one additional winding may laterally surround at least one of the windings from the stack of windings. The stack of windings may be vertically aligned or staggered. The at least one additional winding may be arranged in a vertically aligned stack or a staggered stack. Two or more stacks of windings may be separated by a winding between the stacks. The 3D inductor may occupy a minimal amount of area on the substrate while minimizing fringing capacitance, thereby optimizing the quality factor and self-resonance frequency of the inductor.

An aspect of the disclosure provides an integrated circuit. The integrated circuit can include a semiconductor substrate having a first metallization layer, a second metallization layer, and a third metallization layer. The integrated circuit can include an inductor. The inductor can include a first winding formed from the first metallization layer, a second winding that is formed from the second metallization layer and that at least partially overlaps the first winding, a third winding that is formed from the third metallization layer and that at least partially overlaps the second winding, and a fourth winding that is formed from the third metallization layer and that laterally surrounds the third winding.

An aspect of the disclosure provides wireless circuitry. The wireless circuitry can include a substrate having a first metallization layer, a second metallization layer, and a third metallization layer. The wireless circuitry can include an inductor embedded in the substrate. The inductor can include a first winding in the first metallization layer, a second winding in the second metallization layer, a third winding in the third metallization layer, a fourth winding in the third metallization layer that extends around the third winding, a fifth winding in the second metallization layer that extends around the second winding, and a sixth winding in the first metallization layer that extends around the first winding, wherein the inductor is configured to pass current from the first winding to the second winding, from the second winding to the third winding, from the third winding to the fourth winding, from the fourth winding to the fifth winding, and from the fifth winding to the sixth winding.

An aspect of the disclosure provides an electronic device. The electronic device can include a semiconductor substrate having a first metallization layer, a second metallization layer, and a third metallization layer. The electronic device can include an inductor embedded in the substrate. The inductor can include a first winding in the first metallization layer, a second winding that is in the second metallization layer, that is coupled to the first winding, and that at least partially overlaps the first winding, a third winding that is in the third metallization layer, that is coupled to the second winding, and that at least partially overlaps the second winding, and a fourth winding that is in the first metallization layer and that extends around the first winding, the inductor being configured to pass current from the first winding to the second winding, from the second winding to the third winding, and from the third winding to the fourth winding.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having on-chip inductors in accordance with some embodiments.

FIG. 3 is top view of illustrative on-chip inductors in accordance with some embodiments.

FIG. 4 is a cross-sectional side view of an illustrative three-dimensional on-chip inductor in accordance with some embodiments.

FIG. 5 is a plot of the inductance of a two-dimensional on-chip inductor and an illustrative three-dimensional on-chip inductor in accordance with some embodiments.

FIG. 6 is a plot the quality factor (Q) of a two-dimensional on-chip inductor and an illustrative three-dimensional on-chip inductor in accordance with some embodiments.

FIG. 7 is a cross-sectional side view of an illustrative three-dimensional on-chip inductor having laterally offset windings between columns of aligned windings in accordance with some embodiments.

FIG. 8 is a plot of the inductance of illustrative three-dimensional on-chip inductors having aligned columns of windings and having laterally offset windings between columns of aligned windings in accordance with some embodiments.

FIG. 9 is a plot of the quality factor (Q) of illustrative three-dimensional on-chip inductors having aligned columns of windings and having laterally offset windings between columns of aligned windings in accordance with some embodiments.

FIG. 10 is a cross-sectional side view of an illustrative three-dimensional on-chip inductor having three columns of laterally offset windings in accordance with some embodiments.

FIG. 11 is a cross-sectional side view of an illustrative three-dimensional on-chip inductor having columns of windings laterally separated by additional windings in accordance with some embodiments.

FIG. 12 is a cross-sectional side view showing how the current path between windings of an illustrative three-dimensional on-chip inductor may be inverted in accordance with some embodiments.

### DETAILED DESCRIPTION

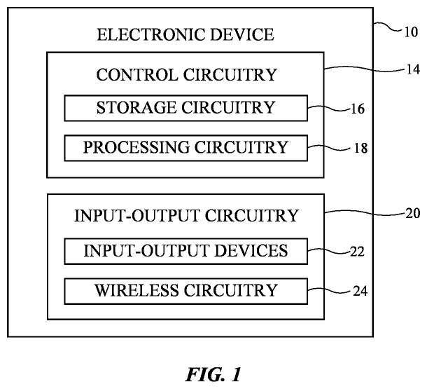

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, part or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, radio-frequency front end circuitry, and/or any other circuitry for transmitting and/or receiving radio-frequency signals using the antenna(s).

Wireless circuitry 24 may transmit and/or receive wireless signals within corresponding frequency bands of the electromagnetic spectrum (sometimes referred to herein as communications bands or simply as “bands”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 1000 GHz (e.g., 6G bands), near-field communications (NFC) frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

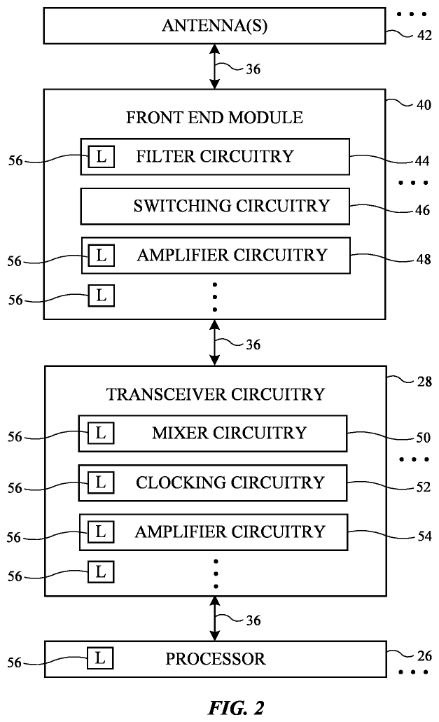

FIG. 2 is a diagram showing illustrative components within wireless circuitry 24. As shown in FIG. 2, wireless circuitry 24 may include one or more processors such as processor(s) 26, radio-frequency (RF) transceiver circuitry such as radio-frequency transceiver 28, radio-frequency front end circuitry such as radio-frequency front end module (FEM) 40, and antenna(s) 42. Processor 26 may include baseband circuitry (e.g., one or more baseband processors), an application processor, a digital signal processor, a microcontroller, a microprocessor, a central processing unit (CPU), a programmable device, an a combination of these circuits, and/or one or more processors within processing circuitry 18 of FIG. 1. Processor 26 may be configured to generate digital (transmit or baseband) signals. Processor 26 may be coupled to transceiver 28 over path 34 (sometimes referred to as a baseband path). Transceiver 28 may be coupled to antenna 42 via radio-frequency transmission line path 36. If desired, one or more radio-frequency front end modules such as radio-frequency front end module 40 may be disposed along radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna (IFA) structures, slot antenna structures, planar inverted-F antenna (PIFA) structures, helical antenna structures, monopole antennas, dipoles, dielectric resonator antenna (DRA) structures, waveguide antenna structures, bowtie antenna structures, hybrids of these designs, etc. If desired, two or more antennas 42 may be arranged into one or more phased antenna arrays (e.g., for conveying radio-frequency signals at millimeter wave frequencies). If desired, parasitic elements may be included in antenna 42 to adjust antenna performance. If desired, antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Front end module (FEM) 40 may include radio-frequency front end circuitry that operates on the radio-frequency signals conveyed (transmitted and/or received) over radio-frequency transmission line path 36. Front end module may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable implementation, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver 28 may include wireless local area network transceiver circuitry that handles WLAN communications bands (e.g., Wi-Fi® (IEEE 802.11) or other WLAN communications bands) such as a 2.4 GHZ WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHZ Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHZ, 5G New Radio Frequency Range 2 (FR2) bands between 20 and 60 GHZ, 6G bands above 100 GHz, etc.), near-field communications (NFC) transceiver circuitry that handles near-field communications bands (e.g., at 13.56 MHZ), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

The term “convey radio-frequency signals” as used herein means the transmission and/or reception of the radio-frequency signals (e.g., for performing unidirectional and/or bidirectional wireless communications with external wireless communications equipment). In performing wireless transmission, processor 26 may provide digital signals to transceiver 28 over path 34. Transceiver 28 may further include circuitry for converting the baseband signals received from processor 26 into corresponding intermediate frequency or radio-frequency signals. For example, transceiver 28 may include mixer circuitry 50 that up-converts (or modulates) the baseband signals to intermediate frequencies (e.g., as intermediate frequency (IF) signals), that up-converts the baseband signals to radio frequencies higher than the intermediate frequencies (e.g., as radio-frequency (RF) signals), and/or that up-converts IF signals to radio frequencies prior to transmission over antenna 42.

Transceiver 28 may also include digital-to-analog converter (DAC) and/or analog-to-digital converter (ADC) circuitry that converts signals between digital and analog domains. Transceiver 28 may include amplifier circuitry 54 (e.g., one or more power amplifiers) that amplify the radio-frequency signals for transmission. Additionally or alternatively, one or more power amplifiers in amplifier circuitry 48 may amplify the radio-frequency signals for transmission. Transceiver 28 may include a transmitter that transmits the radio-frequency signals over antenna 42 via radio-frequency transmission line path 36 and front end module 40. Antenna 42 may transmit the radio-frequency signals to external wireless equipment by radiating the radio-frequency signals into free space (or into free space through a dielectric cover layer on device 10).

In performing wireless reception, antenna 42 may receive radio-frequency signals from external wireless equipment (e.g., from free space). The received radio-frequency signals may be conveyed to transceiver 28 via radio-frequency transmission line path 36 and front end module 40. One or more low noise amplifiers in amplifier circuitry 54 and/or amplifier circuitry 48 may amplify the received signals. Transceiver 28 may include circuitry for converting the received radio-frequency signals into corresponding intermediate frequency or baseband signals. For example, transceiver 28 may use mixer circuitry 52 to downconvert (or demodulate) the received radio-frequency signals to intermediate frequencies, to downconvert the received radio-frequency signals to baseband frequencies (e.g., as baseband signals or baseband data), and/or to downconvert IF signals to baseband frequencies prior to conveying the received signals to processor 26 over path 34.

Mixer circuitry 50 may mix signals with and/or may otherwise be clocked using signals generate by clocking circuitry 52. Clocking circuitry 52 may include local oscillator (LO) circuitry such as local oscillator (LO), voltage controlled oscillator (VCO) circuitry, phase-locked loops, frequency-locked loops, self-injection locked loops, and/or other clocking circuitry. The local oscillator in clocking circuitry 52 can generate oscillator signals that mixer circuitry 50 uses to modulate transmit signals from baseband frequencies to radio frequencies (or intermediate frequencies) and/or to demodulate received signals from radio frequencies to baseband frequencies (or intermediate frequencies).

Wireless circuitry 24 may include inductors that are used in conveying radio-frequency signals. The inductors may include on-chip inductors integrated into a substrate such as a semiconductor substrate (e.g., an integrated circuit (IC) chip). The on-chip inductors may include two-dimensional (2D) on-chip inductors having windings that are confined to a single plane or surface of the substrate. The on-chip inductors may also include three-dimensional (3D) on-chip inductors such as 3D on-chip inductors 56. The windings of 3D on-chip inductors 56 extend beyond a single plane across multiple metallization layers of the substrate. 3D on-chip inductors 56 are sometimes referred to herein simply as 3D inductors 56. On-chip inductors are less bulky and consume much less space in device 10 than discrete surface-mount inductors.

3D inductors 56 may, for example, be implemented or disposed in one or more filters of filter circuitry 44 (e.g., antenna tuning circuitry, impedance matching circuitry, transformer circuitry, duplexer circuitry, diplexer circuitry, multiplexer circuitry, etc.), in one or more amplifiers of amplifier circuitry 48 (e.g., amplifier gain stages, driver stages, matching stages, transformers, etc.), elsewhere in front end module 40, in mixer circuitry 50, in clocking circuitry 52 (e.g., in local oscillator circuitry, VCO circuitry, transformer circuitry, etc.), in amplifier circuitry 54 (e.g., amplifier gain stages, driver stages, matching stages, transformers, etc.), elsewhere in transceiver circuitry 28, in processor 26, in one or more radio-frequency transformers (e.g., DC-to-DC power converters), in impedance matching circuitry, in a wireless power receiving coil (e.g., for receiving wireless power to wirelessly charge device 10), in a wireless power transmitting coil (e.g., for transmitting wireless power to another device), in a near-field communications (NFC) antenna, and/or in power distribution circuitry used by device 10 to power one or more components of device 10 (e.g., from a battery in device 10 or another power source). Implementations in which 3D inductors 56 are used in conveying radio-frequency signals between processor 26 and antenna(s) 42 are described herein as an example. However, in general, 3D inductors 56 may be implemented in any desired circuitry of device 10 for performing any desired operations in device 10 (e.g., 3D inductors 56 need not form a part of wireless circuitry 24).

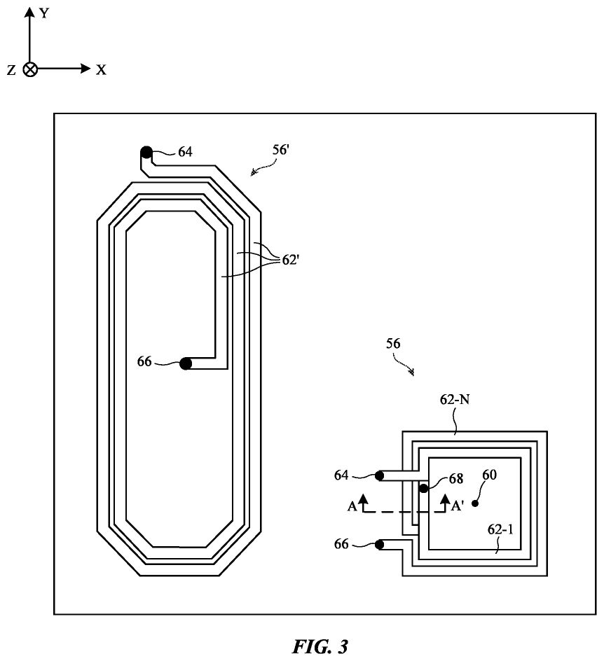

FIG. 3 is a top view showing an illustrative substrate 58 having on-chip inductors. Substrate 58 may include one or more vertically stacked substrate layers (e.g., along the Z-axis). One or more on-chip inductors such as a 2D inductor 56′ and/or 3D inductor 56 may be formed from metallizations or conductive traces that are patterned or disposed onto one or more of the layers of substrate 58.

Substrate 58 may be a printed circuit board (e.g., a rigid printed circuit board, a flexible printed circuit, etc.), a package substrate (e.g., an integrated circuit package substrate), a plastic substrate, a semiconductor substrate such as an integrated circuit (IC) chip, and/or any other desired substrate. Implementations in which substrate 58 is a semiconductor (e.g., silicon) substrate or chip are described herein as an example (e.g., where substrate 58 and the components therein are fabricated using a CMOS process or another semiconductor chip fabrication process). In these implementations, substrate 58 may include stacked semiconductor or insulator layers interleaved with metallization layers.

As shown in FIG. 3, 2D inductor 56′ may include one or more windings 62′ of conductive material (e.g., conductive traces or metal in a metallization layer of substrate 58). Windings 62′ extend from a first terminal 64 of 2D inductor 56′ to a second terminal 66 of 2D inductor 56′ (e.g., around a central axis or opening on substrate 58). 3D inductor 56 may include N windings 62 of conductive material (e.g., conductive traces or metal in two or more metallization layers of substrate 58) that extend from a first terminal 64 of the 3D inductor 56 to a second terminal 66 of 3D inductor 56, around a central axis 60 and a corresponding central opening on substrate 58.

N may be any desired integer greater than or equal to three. 3D inductor 56 may, for example, include a first winding 62-1 in a first metallization layer that vertically overlaps at least one additional winding 62 in at least a second metallization layer of substrate 58 (not shown in FIG. 3 for the sake of clarity). The vertically overlapping (stacked) windings 62 may be coupled together using one or more conductive vias 68 extending through at least one of the layers of substrate 58. At least the Nth winding 62-N of 3D inductor 56 may be formed from the same metallization layer as one of the vertically stacked windings 62 in 3D inductor 56 (e.g., winding 62-1 or one of the other windings vertically overlapping winding 62-1) and may laterally surround that winding on substrate 58. In this way, 3D inductor 56 may exhibit a three dimensional structure on substrate 58. The Nth winding 62-N is coupled to terminal 66 whereas the first winding 62-1 is coupled to terminal 64. Current flows from terminal 64 to terminal 66 through windings 62 in consecutive order from winding 61-1 to winding 62-N (or vice versa).

Each winding 62 of 3D inductor 56 may wind, turn, coil, or wrap one time (e.g., 360 degrees) around central axis 60 or, if desired, one or more of the windings 62 of 3D inductor 56 may wind, turn, coil, or wrap at least partially but less than once around central axis 60 (e.g., 180-360, 270-360, 300-360, or 330-360 degrees around central axis 60). Windings 62 may sometimes also be referred to herein as turns 62. 3D inductor 56 may sometimes also be referred to as a 3D on-chip inductive coil.

In the example of FIG. 3, 2D inductor 56′ and 3D inductor 56 have the same inductance. By implementing the on-chip inductor as a 3D inductor rather than a 2D inductor, the total area occupied by the inductor on substrate 58 is greatly reduced while still allowing the inductor to exhibit similar levels of inductance. The space on substrate 58 saved by implementing the inductor as a 3D inductor may be used to integrated other circuitry into substrate 58 and/or to perform other operations for device 10. At the same time, care should be taken to ensure that 3D inductor 56 exhibits a satisfactory quality factor (Q) and self-resonance frequency (fsr) despite its small size.

The example of FIG. 3 is illustrative and non-limiting. In general, the windings 62 of 3D inductor 56 may have any desired shapes (e.g., having any desired number of curved and/or straight edges) and may follow any desired paths (e.g., having any desired number of straight and/or curved segments). Put differently, 3D inductor 56 may have other layouts on substrate 58.

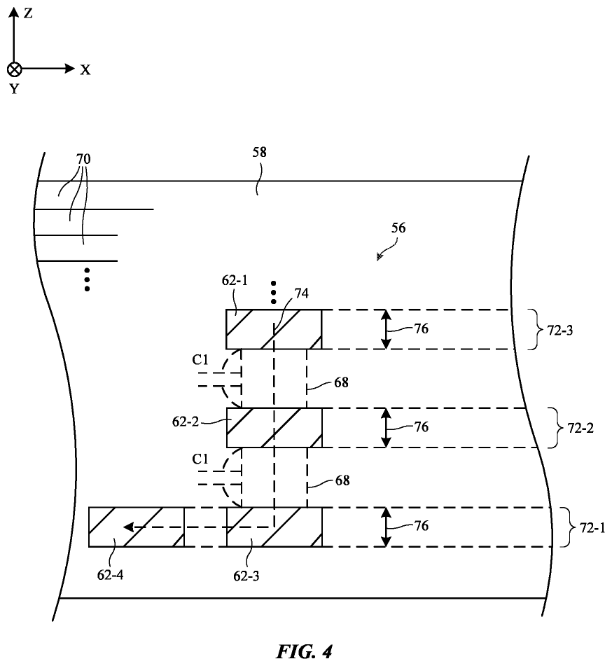

FIG. 4 is a cross-sectional side view of 3D inductor 65 (e.g., as taken in the direction of line AA' of FIG. 3). As shown in FIG. 4, substrate 58 may have a set of stacked layers 70. Layers 70 may be insulator layers or semiconductor layers (e.g., silicon layers), for example. Substrate 58 may also have metallization layers 72 interleaved with layers 70 (sometimes also referred to herein as metal layers 72 or conductive layers 72). Metallization layers 72 may include conductive material such as aluminum, copper, gold, etc.

3D inductor 56 may have at least a first winding 62-1 (e.g., coupled to terminal 64 of FIG. 3), a second winding 62-2, a third winding 62-3, and a fourth winding 62-4. Winding 62-1 may be formed from metallization layer 72-3 (e.g., a first layer of conductive traces patterned in metallization layer 72-3 during fabrication of substrate 58), winding 62-2 may be formed from metallization layer 72-2 (e.g., a second layer of conductive traces patterned in metallization layer 72-2 during fabrication of substrate 58), and winding 62-3 may be formed from metallization layer 72-1 (e.g., a third layer of conductive traces patterned in metallization layer 72-1 during fabrication of substrate 58). Winding 62-4 may also be formed from metallization layer 72-1 and may laterally wrap, extend, or coil around winding 62-3 in metallization layer 72-1 (e.g., winding 62-4 may laterally surround metallization layer 72-1 as viewed in the-Z direction and as shown in FIG. 3, where winding 62-4 forms winding 62-N of FIG. 3).

Winding 62-4 may extend from an end, terminal, or contact on winding 62-3 that is opposite the conductive via 68 that couples winding 62-3 to winding 62-2 (e.g., winding 62-3 may laterally extend around central axis 60 from winding 62-4 to the conductive via 68 coupled to winding 62-3). Winding 62-4 may have a first end, terminal, or contact coupled to winding 62-3 and may have an opposing second end, terminal, or contact that is coupled to or that forms terminal 66 of 3D inductor 56 (FIG. 3). In this way, 3D inductor 56 may be integrated into and embedded within substrate 58. If desired, metallization layer 72-1 or metallization layer 72-3 may be a lower most or uppermost metallization layer of substrate 58. Alternatively, substrate 58 may have one or more metallization layers 72 between metallization layer 72-3 and the upper exterior surface of substrate 58 and/or may have one or more metallization layers 72 between metallization layer 72-1 and the lower exterior surface of substrate 58.

Metallization layers 72-1, 72-2, and 72-3 may be consecutive metallization layers of substrate 58 or, if desired, one or more metallization layers of substrate 58 may be interposed between metallization layers 72-2 and 72-3 and/or between metallization layers 72-1 and 72-2. Metallization layers 72-3, 72-2, and 72-1 may be formed from the same conductive material or, if desired, two or more of metallization layers 72-1, 72-2, and 72-3 may be formed from different conductive materials. As one example, metallization layer 72-3 and winding 62-1 are formed from aluminum (e.g., an aluminum top layer of substrate 58), metallization layer 72-2 and winding 62-2 are formed from copper, and metallization layer 72-1 and windings 62-2 and 62-4 are formed from copper.

Metallization layers 72-1, 72-2, and 72-3 may be thick metallization layers of substrate 58 (e.g., having a thickness 76 greater than or equal to 1 micron). Thicker thicknesses 76 may allow for greater inductive performance by 3D inductor 56 but also consume more space in substrate 58 than thinner thicknesses 76. Metallization layers 72-1, 72-2, and 72-3 may have the same thickness 76 or, if desired, two or more of metallization layers 72-1, 72-2, and 72-3 may have different thicknesses 76. As one example, metallization layer 72-3 may have a thickness between 2 and 3 microns whereas metallization layers 72-1 and 72-2 have a thickness greater than 3 microns (e.g., metallization layer 72-3 may be thinner than metallization layers 72-1 and 72-2). Substrate 58 may also have thin metallization layers that are not used to form 3D inductor 56. The thin metallization layers may have a thickness less than 0.1 micron, for example.

One or more conductive vias 68 may couple a terminal or contact on winding 62-1 to a terminal or contact on winding 62-2 (e.g., extending through one or more layers 70 between metallization layers 72-2 and 72-3). One or more conductive vias 68 may couple a terminal or contact on winding 62-2 to a terminal or contact on winding 62-3 (e.g., extending through one or more layers 70 between metallization layers 72-2 and 72-3). The conductive via coupling winding 62-1 to winding 62-2 may be laterally aligned with the conductive via coupling winding 62-2 to winding 62-3 or may be offset or located elsewhere along the lateral area of the windings.

When coupled together in this way, current may flow through 3D inductor 56 from terminal 64 (FIG. 3), through winding 62-1 (e.g., around the central axis of the inductor), through a conductive via 68 between metallization layers 72-3 and 72-2 to winding 62-2, through winding 62-2 (e.g., around the central axis of the inductor), through a conductive via 68 between metallization layers 72-2 and 72-1 to winding 62-3, through winding 62-3 (e.g., around the central axis of the conductor), and through winding 62-4 (e.g., around the central axis of the conductor) to terminal 66 (FIG. 3), as shown by current path 74. The portions of windings 62-1 and 62-2 not shorted together by the corresponding conductive via 68 may exhibit a capacitance C1. Similarly, the portions of windings 62-2 and 62-3 not shorted together by the corresponding conductive via 68 may exhibit capacitance C1. Implementing 3D inductor 56 in this way may serve to prevent parasitic capacitance between thick metallization in substrate 58 from dominating the response of 3D inductor 56, thereby optimizing the self-resonance frequency of the inductor.

In the example of FIG. 4, 3D inductor 56 includes a single column of vertically stacked or aligned windings 62-1. 62-2, and 62-3, where winding 62-4 is formed as wind-out of winding 62-3 within metallization layer 72-1. The example of FIG. 4 is illustrative and non-limiting. If desired, 3D inductor 56 may be distributed across two metallization layers (e.g., winding 62-2 may be omitted), may include more than three vertically aligned windings, and/or may include additional windings 62 laterally surrounding winding 62-4 (e.g., where the additional winding(s) extend or wind out from an end of winding 62-4 to terminal 66 (FIG. 3)).

Curve 80 of FIG. 5 plots the inductance of 2D inductor 56′ (FIG. 3) as a function of frequency. Curve 82 of FIG. 5 plots the inductance of 3D inductor 56 when sized to exhibit a 65% area reduction relative to 2D inductor 56′. As shown by curves 80 and 82, implementing the inductor as 3D inductor 56 produces a similar inductive response with a slight increase in frequency while significantly reducing chip area.

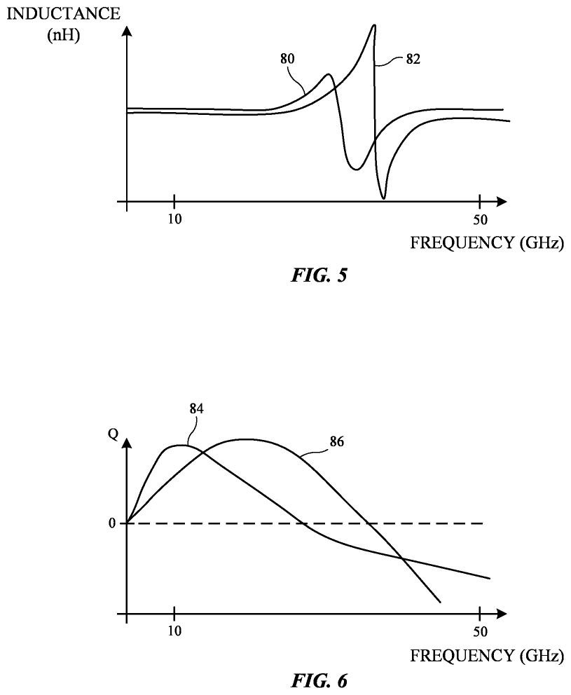

Curve 84 of FIG. 6 plots the Q of 2D inductor 56′ (FIG. 3) as a function of frequency. Curve 86 of FIG. 6 plots the Q of 3D inductor 56. As shown by curves 86 and 84, implementing the inductor as 3D inductor 56 produces higher Q at higher frequencies than when a 2D inductor is used, which is particularly beneficial for operation at relatively high frequencies such as frequencies associated with 5G NR communications, intermediate frequency signal propagation, etc. This may also serve to shift the self-resonance frequency of the inductor to higher frequencies (e.g., from around 24 GHz to around 30 GHZ). The example of FIGS. 5 and 6 is illustrative and non-limiting. In practice, curves 80-86 may have other shapes and 3D inductor 56 may be configured to operate at any desired frequencies.

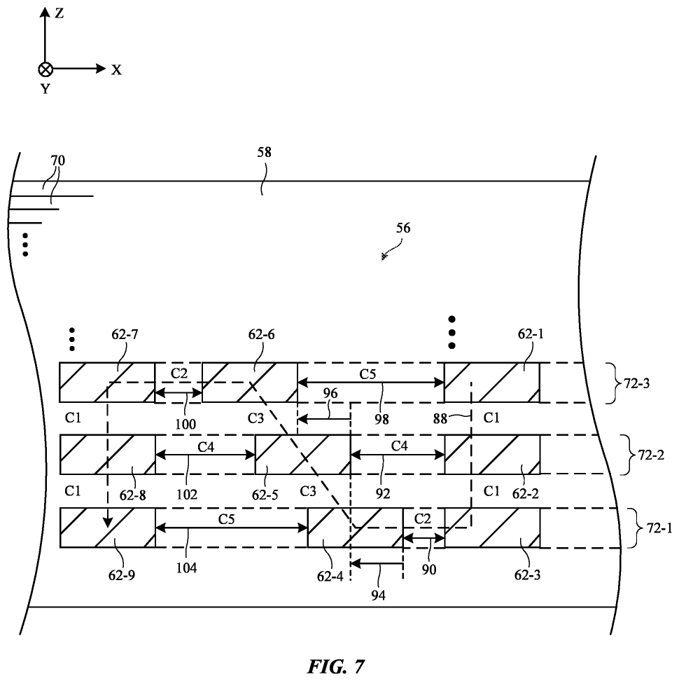

If desired, 3D inductor 56 may include additional windings 62 extending from winding 62-4. FIG. 7 shows one example in which 3D inductor 56 includes a laterally offset column of windings extending from winding 62-4 to an additional vertically-aligned column of windings. As shown in FIG. 7, 3D inductor 56 may include a fifth winding 62-5 formed from metallization layer 72-2 and extending from the end of winding 62-4 opposite winding 62-3. 3D inductor 56 may also include a sixth winding 62-6 formed from metallization layer 72-3 and extending from the end of winding 62-5 opposite winding 62-4. 3D inductor 56 may further include a seventh winding 62-7 formed from metallization layer 72-3 and extending from the end of winding 62-6 opposite winding 62-5. In addition, 3D inductor 56 may include an eighth winding 62-8 formed from metallization layer 72-2 and extending from an end of winding 62-7. Further, 3D inductor 56 may include a ninth winding 62-9 formed from metallization layer 72-1 and extending from an end of winding 62-8. Winding 62-9 may be coupled to terminal 66 (FIG. 3).

The conductive vias 68 that couple the windings 62 of 3D inductor 56 together across metallization layers 72-1, 72-2, and 72-3 have been omitted from FIG. 7 for the sake of clarity. However, the lateral end of winding 62-4 opposite winding 62-3 may be coupled to a first lateral end of winding 62-5 by a conductive via extending through the layer(s) 70 of substrate 58 between metallization layers 72-1 and 72-2. Winding 62-5 may laterally extend, turn, coil, or wrap around (e.g., may surround) winding 62-2 in metallization layer 72-2 from its first lateral end to an opposing second lateral end (e.g., without being coupled or shorted to winding 62-2 within metallization layer 72-2).

The second lateral end of winding 62-5 may be coupled to a first lateral end of winding 62-6 by a conductive via extending through the layer(s) 70 of substrate 58 between metallization layers 72-2 and 72-3. Winding 62-6 may laterally extend, turn, coil, or wrap around (e.g., may surround) winding 62-1 in metallization layer 72-3 from its first lateral end to an opposing second lateral end (e.g., without being coupled or shorted to winding 62-1 within metallization layer 72-3).

Winding 62-7 may have a first lateral end extending from the second lateral end of winding 62-6 in metallization layer 72-3. Winding 62-7 may laterally extend, turn, coil, or wrap around (e.g., may surround) winding 62-6 and winding 62-1 in metallization layer 72-3 from its first end to an opposing second lateral end (e.g., without being coupled or shorted to winding 62-1 within metallization layer 72-3). The second lateral end of winding 62-7 may be coupled to a first lateral end of winding 62-8 by a conductive via extending through the layer(s) 70 of substrate 58 between metallization layers 72-2 and 72-3. Winding 62-8 may laterally extend, turn, coil, or wrap around (e.g., may surround) winding 62-5 and winding 62-2 in metallization layer 72-2 from its first lateral end to an opposing second lateral end (e.g., without being coupled or shorted to winding 62-5 or winding 62-2 within metallization layer 72-2).

The second lateral end of winding 62-8 may be coupled to a first lateral end of winding 62-9 by a conductive via extending through the layer(s) 70 of substrate 58 between metallization layers 72-2 and 72-1. Winding 62-9 may laterally extend, turn, coil, or wrap around (e.g., may surround) winding 62-4 and winding 62-3 in metallization layer 72-1 from its first lateral end to an opposing second lateral end (e.g., without being coupled or shorted to winding 62-4 or winding 62-3 within metallization layer 72-1).

When coupled together in this way, current may flow through 3D inductor 56 from terminal 64 (FIG. 3), through winding 62-1 (e.g., around the central axis of 3D inductor 56), through a first conductive via between metallization layers 72-3 and 72-2 to winding 62-2, through winding 62-2 (e.g., around the central axis of 3D inductor 56), through a first conductive via between metallization layers 72-2 and 72-1 to winding 62-3, through winding 62-3 to winding 62-4 (e.g., around the central axis of 3D inductor 56), through winding 62-4 (e.g., around the central axis of 3D inductor 56), through a second conductive via between metallization layers 72-2 and 72-1 to winding 62-5, through winding 62-5 (e.g., around the central axis of 3D inductor 56), through a second conductive via between metallization layers 72-2 and 72-3 to winding 62-6, through winding 62-6 to winding 62-7 (e.g., around the central axis of 3D inductor 56), through winding 62-7 (e.g., around the central axis of 3D inductor 56), through a third conductive via between metallization layers 72-2 and 72-3 to winding 62-8, through winding 62-8 (e.g., around the central axis of 3D inductor 56), through a third conductive via between metallization layers 72-1 and 72-2 to winding 62-9, and through winding 62-9 (e.g., around the central axis of 3D inductor 56) to terminal 66 (FIG. 3), as shown by current path 88.

Windings 62-1, 62-2, and 62-3 may form a first column of (vertically) aligned or stacked windings in 3D inductor 56 (e.g., the conductive material in windings 62-1 through 62-3 completely overlaps when viewed in the-Z direction). Windings 62-7, 62-8, and 62-9 may form a second column of (vertically) aligned or stacked windings in 3D inductor 56 (e.g., the conductive material in windings 62-7 through 62-9 completely overlaps when viewed in the-Z direction). On the other hand, windings 62-4, 62-5, and 62-6 may be laterally offset with respect to each other. In other words, windings 62-4, 62-5, and 62-6 may form a laterally offset or staggered stack (column) of windings (e.g., the conductive material in winding 62-5 may be partially non-overlapping with respect to the conductive material in winding 62-4 and with respect to the conductive material in winding 62-6 and the conductive material in winding 62-4 may be partially non-overlapping with respect to the conductive material in winding 62-6 when viewed in the-Z direction).

For example, as shown in FIG. 7, winding 62-4 may be laterally separated from winding 62-3 by distance 90 (e.g., the diameter of winding 62-4 may be greater than the diameter of winding 62-3 by twice distance 90). Winding 62-5 may be laterally offset with respect to winding 62-4 by offset 94 (e.g., the diameter of winding 62-5 may be greater than the diameter of winding 62-4 by twice offset 94). As such, winding 62-5 may be laterally separated from winding 62-2 by a distance 92 that is greater than distance 90 by offset 94 (e.g., the diameter of winding 62-5 may be greater than the diameter of winding 62-2 by twice distance 92). In addition, winding 62-6 may be laterally offset with respect to winding 62-5 by offset 96 (e.g., the diameter of winding 62-6 may be greater than the diameter of winding 62-5 by twice offset 96). As such, winding 62-6 may be laterally separated from winding 62-1 by a distance 98 that is greater than distance 92 by offset 96 (e.g., the diameter of winding 62-6 may be greater than the diameter of winding 62-1 by twice distance 98).

At the same time, winding 62-6 may be laterally separated from winding 62-7 by distance 100 (e.g., the diameter of winding 62-7 may be greater than the diameter of winding 62-6 by twice distance 100). Winding 62-8 may be laterally separated from winding 62-5 by distance 102 (e.g., the diameter of winding 62-8 may be greater than the diameter of winding 62-5 by twice distance 102). Winding 62-9 may be laterally separated from winding 62-4 by distance 104 (e.g., the diameter of winding 62-9 may be greater than the diameter of winding 62-4 by twice distance 104). Distance 104 may be equal to distance 98 or may be different than distance 98. Distance 102 may be equal to distance 92 or may be different than distance 92. Distance 100 may be the same as distance 90 or may be different than distance 90.

The portions of windings 62-7 and 62-8 not shorted together by the corresponding conductive via 68 may exhibit capacitance C1. The portions of windings 62-8 and 62-9 not shorted together by the corresponding conductive via 68 may exhibit capacitance C1. The portions of windings 62-7 and 62-6 not shorted together may exhibit capacitance C2. The portions of windings 62-4 and 62-3 not shorted together may exhibit capacitance C2. In implementations where windings 62-4 through 62-6 are arranged in a vertically aligned stack (column), the same relatively high capacitance C2 will be present between adjacent windings in each metallization layer.

Staggering or offsetting windings 62-4 through 62-6 as shown in FIG. 7 may serve to minimize the contribution of fringing capacitances between windings of the same metallization layer to the self-resonance frequency of 3D inductor 56, thereby optimizing performance of the inductor despite its small lateral area. For example, when distance 100 is equal to distance 90, distance 102 is equal to distance 92, and distance 104 is equal to distance 98, a capacitance C4 may be established between windings 62-5 and 62-8 and between windings 62-5 and 62-2 that is less than capacitance C2. Similarly, a capacitance C5 may be established between windings 62-6 and 62-1 and between windings 62-9 and 62-4 that is less than capacitance C2. As each winding contributes equal inductance and voltage drop to the inductor, this may serve to produce a similar amount of capacitive energy storage between each pair of vertically and laterally adjacent windings in 3D inductor 56. This prevents any single fringing capacitance in 3D inductor 56 from dominating the self-resonance frequency, which serves to increase the self-resonance frequency and Q of the inductor relative to implementations where windings 62-4 through 62-6 are arranged in a vertically aligned column.

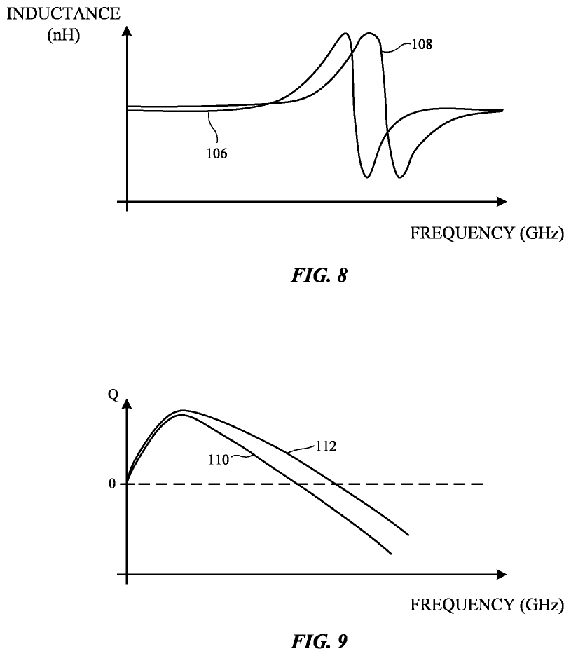

Curve 106 of FIG. 8 plots the inductance of 3D inductor 56 as a function of frequency when windings 62-4 through 62-6 are arranged in a vertically aligned column. Curve 108 of FIG. 8 plots the inductance of 3D inductor 56 when windings 62-4 through 62-6 are laterally offset as shown in FIG. 7. As shown by curves 106 and 108, offsetting windings 62-4 through 62-6 produces a similar inductive response with a slight increase in frequency.

Curve 110 of FIG. 9 plots the Q of 3D inductor 56 as a function of frequency when windings 62-4 through 62-6 are arranged in a vertically aligned column. Curve 112 of FIG. 9 plots the inductance of 3D inductor 56 when windings 62-4 through 62-6 are laterally offset as shown in FIG. 7. As shown by curves 110 and 112, offsetting windings 62-4 through 62-6 serves to improve Q at both the self-resonance frequency and peak, while also shifting self-resonance frequency slightly higher in frequency (e.g., from 17 GHz to 20 GHZ). The example of FIGS. 8 and 9 is illustrative and non-limiting. In practice, curves 106-112 may have other shapes and 3D inductor 56 may be configured to operate at any desired frequencies.

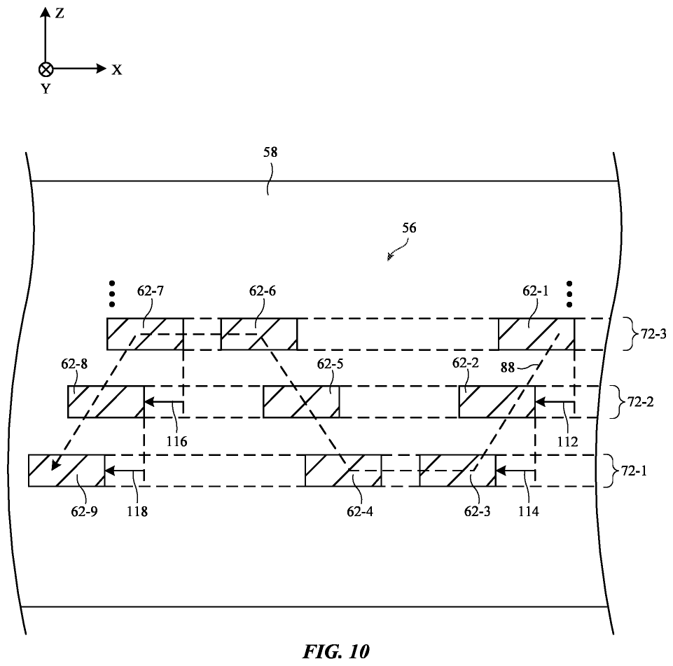

The example of FIG. 7 is illustrative and non-limiting. If desired, windings 62-7 through 62-9 may be omitted (e.g., winding 62-6 may be coupled to terminal 66 of FIG. 3). More generally, any desired combination of one or more of windings 62-9 through 62-5 may be omitted. 3D inductor 56 may include additional windings stacked over windings 62-7, 62-6. and/or 62-1. 3D inductor 56 may include additional windings stacked under windings 62-9, 62-4, and/or 62-3. 3D inductor 56 may include additional windings laterally surrounding windings 62-7. 62-8, and/or 62-9. 3D inductor 56 may include one or more concentric repetitions of all the windings shown in FIG. 7 or any desired subset of the windings shown in FIG. 7. If desired, windings 62-4 through 62-6 may be arranged in a vertically aligned column. If desired, windings 62-7 through 62-9 and/or windings 62-1 through 62-3 may also be laterally offset like windings 62-4 through 62-6, as shown in the example of FIG. 10.

As shown in FIG. 10, rather than completely overlapping each other, windings 62-1 through 62-3 may be partially non-overlapping with respect to each other (e.g., may be laterally offset or staggered). For example, winding 62-2 may be laterally offset with respect to winding 62-1 by offset 112 (e.g., the diameter of winding 62-2 may be greater than the diameter of winding 62-1 by twice offset 112). Additionally or alternatively, winding 62-3 may be laterally offset with respect to winding 62-2 by offset 114.

Additionally or alternatively, rather than completely overlapping each other, windings 62-7 through 62-9 may be partially non-overlapping with respect to each other (e.g., may be laterally offset or staggered). For example, winding 62-8 may be laterally offset with respect to winding 62-7 by offset 116 (e.g., the diameter of winding 62-8 may be greater than the diameter of winding 62-7 by twice offset 116). Additionally or alternatively, winding 62-9 may be laterally offset with respect to winding 62-8 by offset 118. If desired, the lateral offsets and thus the lateral distance between windings 62-9 and 62-4 and between windings 62-6 and 62-1 may be the same. Similarly, the lateral distance between windings 62-8 and 62-5 may be the same as the lateral distance between windings 62-5 and 62-2 may be the same. Further, the lateral distance between windings 62-7 and 62-6 may be the same as the lateral distance between windings 62-4 and 62-3 may be the same. Alternatively, some or all of the distances may be different.

Offsetting windings 62-7 through 62-9 and/or windings 62-1 through 62-3 in this way may further decrease the capacitance between windings 62-6 and 62-1, between windings 62-5 and 62-2, between windings 62-5 and 62-8, and/or between windings 62-9 and 62-4 (e.g., to prevent any one capacitance or capacitive energy storage mode from dominating the self-resonance frequency of the inductor). If desired, windings 62-9 through 62-7 may be omitted (e.g., windings 62-1 through 62-6 may be arranged to exhibit in a V-shaped cross-sectional profile). If desired, windings 62-5 through 62-9 may be omitted, windings 62-6 through 62-9 may be omitted, windings 62-8 and 62-9 may be omitted, etc. More generally, any desired combination of one or more of windings 62-5 through 62-9 may be omitted.

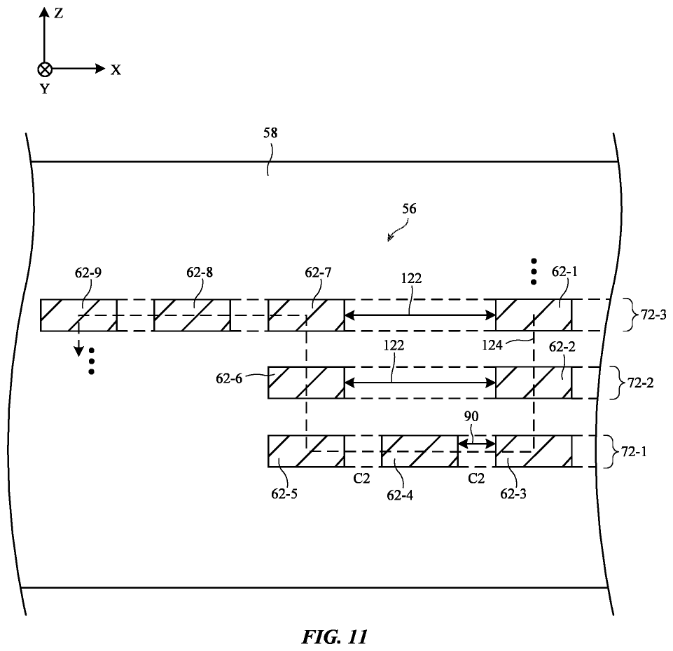

If desired, 3D inductor 56 may have columns of windings 62 that are laterally separated by at least one additional winding. FIG. 11 shows one example of how 3D inductor 56 may have columns of windings 62 that are laterally separated by at least one additional winding. As shown in FIG. 11, windings 62-5 through 62-7 may be formed from metallization layers 72-1 through 72-3 respectively. Windings 62-5 through 62-7 and windings 62-1 through 62-3 may be arranged in respective vertically aligned (stacked) columns. If desired, windings 62-8, 62-9, and/or additional windings 62 may be coupled to winding 62-7 and may be arranged in any desired manner (e.g., as a repetition of windings 62-1 through 62-7, in vertically aligned columns, in laterally offset columns, surrounding each other within the same metallization layer, etc.). Current may flow through 3D inductor 56 in the direction of current path 124.

Winding 62-5 may extend from an end of winding 62-4 and may laterally surround winding 62-4. In this way, winding 62-4 laterally separates winding 62-5 from winding 62-3. At the same time, winding 62-4 configures winding 62-6 to be laterally separated from winding 62-2 and configures winding 62-7 to be laterally separated from winding 62-1 by a distance 122 that is at least twice distance 90. This serves to decrease the capacitance between windings 62-6 and 62-2 and between windings 62-7 and 62-1 relative to implementations where 3D inductor 56 includes a vertically aligned column of windings extending above winding 62-4, which would otherwise be laterally separated from windings 62-1 through 62-3 by distance 90.

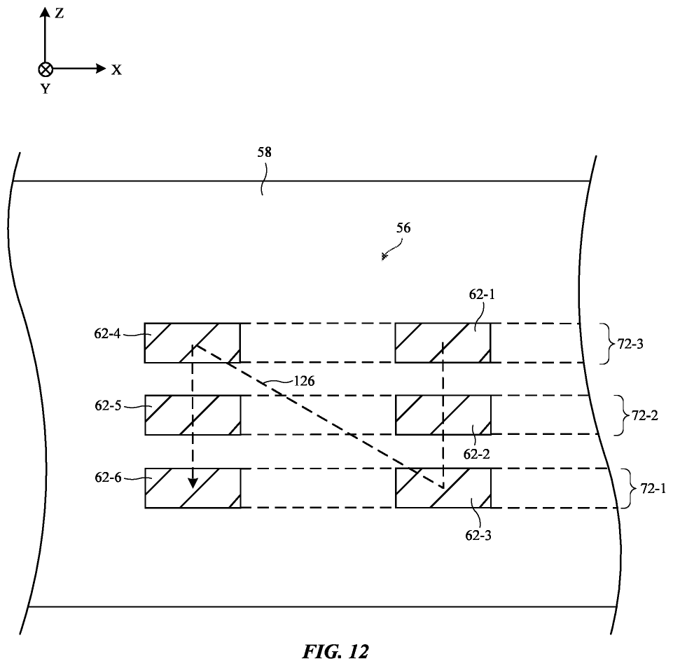

In general, 3D inductor 56 may be provided with any desired number of three or more windings arranged in any desired combination of the winding arrangements described herein. If desired, the windings may be coupled together so that the current path in the inductor flows in different orders between metallization layers 72-1 through 72-6. For example, the coupling between the windings in any of the arrangements described herein may be at least partially inverted to invert the current path through the windings and metallization layers. FIG. 12 shows one example in which 3D inductor 56 includes two vertically aligned columns of windings with an inverted coupling.

As shown in FIG. 12, rather than being formed from metallization layer 72-1, winding 62-4 may be formed from metallization layer 72-3 (e.g., laterally surrounding winding 62-1 without being shorted to winding 62-1 within metallization layer 72-3). Winding 62-5 may be formed from metallization layer 72-2 (e.g., laterally surrounding winding 62-2 without being shorted to winding 62-2 within metallization layer 72-2). Winding 62-6 may be formed from metallization layer 72-1 (e.g., laterally surrounding winding 62-3 without being shorted to winding 62-3 within metallization layer 72-1). One or more conductive vias may couple the second lateral end of winding 62-3 in metallization layer 62-3 to the first lateral end of winding 62-4 in metallization layer 72-3. Conductive vias may couple winding 62-4 to winding 62-5 and may couple winding 62-5 to winding 62-6.

Inverting the coupling between windings across metallization layers 72-1 through 72-3 in this way may configure current to flow within 3D inductor 56 along current path 126, which jumps from winding 62-3 in metallization layer 72-1 to winding 62-4 in metallization layer 72-3 before passing back down to metallization layer 72-1 through windings 62-5 and 62-6. This may serve to reduce the voltage difference between the first and last winding in 3D inductor 56 relative to implementations where winding 62-4 is formed from metallization layer 72-1 and winding 62-6 is formed from metallization layer 72-3. If only considering side-wall fringing capacitance, this can reduce the total equivalent capacitance by around 22%, producing a modest improvement in self-resonance frequency and Q. Any of the winding layouts described herein may be provided with an inverted current path of this type if desired.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is illustrative and various modifications can be made to the described embodiments. The foregoing embodiments may be implemented individually or in any combination.

What is claimed is:

1. An integrated circuit comprising:
a semiconductor substrate having a first metallization layer, a second metallization layer, and a third metallization layer; and
an inductor that includes
a first winding formed from the first metallization layer,
a second winding that is formed from the second metallization layer and that at least partially overlaps the first winding,
a third winding that is formed from the third metallization layer and that at least partially overlaps the second winding, and
a fourth winding that is formed from the third metallization layer and that laterally surrounds the third winding.

2. The integrated circuit of claim 1, wherein the inductor has a first terminal on the first winding, the inductor has a second terminal on the second winding, and the inductor is configured to pass current from the first terminal to the second winding through the first winding, from the first winding to the third winding through the second winding, and from the third winding to the second terminal through the fourth winding.

3. The integrated circuit of claim 2, wherein the first winding, the second winding, the third winding, and the fourth winding each wraps at least 300 degrees around a central axis of the inductor.

4. The integrated circuit of claim 1, wherein the inductor further comprises:
a fifth winding that is formed from the second metallization layer, that is coupled to the fourth winding, and that laterally surrounds the second winding.

5. The integrated circuit of claim 4, wherein the fifth winding is laterally offset with respect to the fourth winding.

6. The integrated circuit of claim 5, wherein the inductor further comprises:
a sixth winding that is formed from the first metallization layer, that is coupled to the fifth winding, that laterally surrounds the first winding, and that is laterally offset with respect to the fifth winding.

7. The integrated circuit of claim 6, wherein the first winding, the second winding, and the third winding are arranged in a vertically aligned stack.

8. The integrated circuit of claim 7, wherein the inductor further comprises:
a seventh winding that is formed from the first metallization layer, that is coupled to the sixth winding, and that laterally surrounds the sixth winding;
an eighth winding that is formed from the second metallization layer, that is coupled to the seventh winding, and that laterally surrounds the fifth winding; and
an ninth winding that is formed from the third metallization layer, that is coupled to the eighth winding, and that laterally surrounds the fourth winding, wherein the seventh winding, the eighth winding, and the ninth winding are arranged in an additional vertically aligned stack.

9. The integrated circuit of claim 8, wherein the first winding is laterally separated from the sixth winding by a first distance, the ninth winding is laterally separated from the fourth winding by the first distance, the eighth winding is laterally separated from the fifth winding by a second distance shorter than the first distance, the fifth winding is laterally separated from the second winding by the second distance, the seventh winding is laterally separated from the sixth winding by a third distance less than the second distance, and the fourth winding is laterally separated from the third winding by the third distance.

10. The integrated circuit of claim 6, wherein the first winding is laterally offset with respect to the second winding and the second winding is laterally offset with respect to the third winding.

11. The integrated circuit of claim 10, wherein the inductor further comprises:
a seventh winding that is formed from the first metallization layer, that is coupled to the sixth winding, and that laterally surrounds the sixth winding;
an eighth winding that is formed from the second metallization layer, that is coupled to the seventh winding, that laterally surrounds the fifth winding, and that is laterally offset with respect to the seventh winding; and
an ninth winding that is formed from the third metallization layer, that is coupled to the eighth winding, that laterally surrounds the fourth winding, and that is laterally offset with respect to the eighth winding.

12. The integrated circuit of claim 8, wherein the first winding is laterally separated from the sixth winding by a first distance, the ninth winding is laterally separated from the fourth winding by the first distance, the eighth winding is laterally separated from the fifth winding by a second distance shorter than the first distance, the fifth winding is laterally separated from the second winding by the second distance, the seventh winding is laterally separated from the sixth winding by a third distance less than the second distance, and the fourth winding is laterally separated from the third winding by the third distance.

13. The integrated circuit of claim 1, wherein the inductor further comprises:
a fifth winding that is formed from the third metallization layer, that is coupled to the fourth winding, and that laterally surrounds the fourth winding;
a sixth winding that is formed from the second metallization layer, that is coupled to the fifth winding, and that laterally surrounds the second winding, and that is laterally separated from the second winding; and
a seventh winding that is formed from the first metallization layer, that is coupled to the sixth winding, and that laterally surrounds the first winding.

14. The integrated circuit of claim 13, wherein the first winding, the second winding, and the third winding are arranged in a first vertically aligned stack, and the fifth winding, the sixth winding, and the seventh winding are arranged in a second vertically aligned stack.

15. The integrated circuit of claim 1, wherein the inductor further comprises:
a sixth winding that is formed from the second metallization layer, that is coupled to the fourth winding, and that laterally surrounds the second winding; and
a seventh winding that is formed from the first metallization layer, that is coupled to the sixth winding and the third winding, and that laterally surrounds the first winding, wherein current is configured to flow from the first winding to the second winding, from the second winding to the third winding, from the third winding to the seventh winding, from the seventh winding to the sixth winding, and from the sixth winding to the fourth winding.

16. Wireless circuitry comprising:
a substrate having a first metallization layer, a second metallization layer, and a third metallization layer; and
an inductor embedded in the substrate, the inductor including
a first winding in the first metallization layer,
a second winding in the second metallization layer,
a third winding in the third metallization layer,
a fourth winding in the third metallization layer that extends around the third winding,
a fifth winding in the second metallization layer that extends around the second winding, and
a sixth winding in the first metallization layer that extends around the first winding, wherein the inductor is configured to pass current from the first winding to the second winding, from the second winding to the third winding, from the third winding to the fourth winding, from the fourth winding to the fifth winding, and from the fifth winding to the sixth winding.

17. The wireless circuitry of claim 16, wherein the fourth winding is laterally separated from the third winding by a first distance, the fifth winding is laterally separated from the second winding by a second distance greater than the first distance, the sixth winding is laterally separated from the first winding by a third distance greater than the second distance, the first winding, the second winding, and the third winding are arranged in a vertically aligned stack, and the fourth winding, the fifth winding, and the sixth winding are arranged in a staggered stack.

18. The wireless circuitry of claim 16, wherein the fourth winding is laterally separated from the third winding by a first distance, the fifth winding is laterally separated from the second winding by a second distance greater than the first distance, the sixth winding is laterally separated from the first winding by a third distance greater than the second distance, the first winding, the second winding, and the third winding are arranged in a first staggered stack, and the fourth winding, the fifth winding, and the sixth winding are arranged in a second staggered stack.

19. An electronic device comprising:
a semiconductor substrate having a first metallization layer, a second metallization layer, and a third metallization layer; and
an inductor embedded in the substrate, the inductor including
a first winding in the first metallization layer,
a second winding that is in the second metallization layer, that is coupled to the first winding, and that at least partially overlaps the first winding,
a third winding that is in the third metallization layer, that is coupled to the second winding, and that at least partially overlaps the second winding, and
a fourth winding that is in the first metallization layer and that extends around the first winding, the inductor being configured to pass current from the first winding to the second winding, from the second winding to the third winding, and from the third winding to the fourth winding.

20. The electronic device of claim 19, wherein the inductor further comprises:
a fifth winding that is in the second metallization layer, that is coupled to the fourth winding, and that extends around the second winding, and
a sixth winding that is in the third metallization layer, that is coupled to the fifth winding, and that extends around the third winding, the inductor being configured to pass current from the fourth winding to the fifth winding and from the fifth winding to the sixth winding.
